(19) United States
(12) Patent Application Publication
(10) Pub. No.: US 2003/0077917 A1
(43) Pub. Date: Apr. 24, 2003

(54) Method of fabricating a void-free barrier layer

(76) Inventors: Ping-Wei Lin, Hsinchu (TW); Ming-Kuan Kao, Hsinchu (TW); Cheng Chung Hsieh, Taichung (TW)

Correspondence Address: BIRCH STEWART KOLASCH & BIRCH, PO BOX 747, FALLS CHURCH, VA, 22040-0747, US

(21) Appl. No.: 09/982,867

(22) Filed: Oct. 22, 2001

(51) Int. Cl. H01L 21/4763; H01L 21/31

(52) U.S. Cl. 438/778; 438/788; 438/792

(57) ABSTRACT

A method of fabricating a void-free barrier layer located on a semiconductor substrate. First, conductive structures are defined on the semiconductor substrate. Second, a barrier layer is deposited over the conductive structures, wherein the barrier layer has a void between the conductive structures. Third, argon gas is introduced into a HDPCVD chamber to sputter the barrier layer so that the void is eliminated.

### BACKGROUND OF THE INVENTION

1. Field of the Invention

The present invention relates to the manufacturing of semiconductor devices, more particularly, to a method of manufacturing a void-free barrier layer in a high density plasma chemical vapor deposition (HDPCVD) chamber by introducing argon gas to generate argon plasma.

2. Description of the Related Art

During the manufacturing of semiconductor devices, a barrier layer is formed, for example by plasma enhanced chemical vapor deposition (PECVD), on a semiconductor substrate having polysilicon gates/metal silicides, followed by depositing a dielectric layer over the barrier layer. As the design rule of the semiconductor devices continues to shrink, the void between polysilicon gates becomes smaller and smaller. This can result in the formation of a void inside the narrow void during deposition of the barrier layer by chemical vapor deposition. The existence of the void can cause reliability problems of a semiconductor device due to entrapment of gases or liquids in the void.

FIGS. 1A to 1C depict a process for forming a barrier layer on a semiconductor substrate according to the prior art.

FIG. 1A illustrates a semiconductor substrate 10. Conductive structures 11 such as polysilicon gates or metal lines are defined on the semiconductor substrate 10. There is a void G between the conductive structures 11.

Next, as shown in FIG. 1B, a barrier layer 13 is deposited by plasma enhanced chemical vapor deposition (PECVD). A void 14 is generated because of the narrow void G and insufficient step coverage during deposition.

Next, as shown in FIG. 1C, the semiconductor substrate 10 describe above is placed in a HDPCVD chamber, a dielectric layer 15 is deposited by HDPCVD over the barrier layer 13 having a void in the void between conductive structures 11.

However, the barrier layer 13 having a void 14 between the conductive structure 11 can cause reliability problems in the semiconductor device due to entrapment of gases or liquids in the void.

### SUMMARY OF THE INVENTION

In view of the above disadvantages, an object of the invention is to provide a method of fabricating a void-free barrier layer located on a semiconductor substrate before the dielectric layer is formed.

It is another object of the invention to solve the reliability problems of a semiconductor device caused by a void in the barrier layer.

Another object of the invention is to provide a method of fabricating a void-free barrier layer located on a semiconductor substrate in the same HDPCVD chamber before the dielectric layer is formed.

Accordingly, the above objects are attained by providing a method of fabricating a void-free barrier layer located on a semiconductor substrate, comprising the steps of: (a) forming conductive structures on the semiconductor substrate; (b) depositing a barrier layer over the conductive structures, wherein the barrier layer has a void between the conductive structures; (c) introducing argon gas into a chamber of high density plasma chemical vapor deposition to sputter the barrier layer so that the void is eliminated. The barrier layer is preferably formed by PECVD.

In an embodiment of the invention, this method further comprises the step of depositing a dielectric layer over the barrier layer by high density plasma chemical vapor deposition. Also, the deposition/sputtering (DIS) ratio for depositing the dielectric layer is between approximately 2.0 and 8.0.

In another embodiment of the invention, the barrier layer is preferably silicon nitride, silicon oxide, or silicon rich oxide. Also, the argon gas can be introduced while a bias voltage is applied to the chamber. Moreover, the flow rate of the argon gas can be 500 to 4000 sccm. Also, in step (c) above, the barrier layer is sputtered for about 1 to about 3 seconds.

Furthermore, the above objects are also attained by a method of fabricating a void-free barrier layer located on a semiconductor substrate having a barrier layer with a void, comprising the steps of: placing the semiconductor substrate in a chamber of high density plasma chemical vapor deposition; introducing an inert gas, such as argon, into the chamber for sputtering of the barrier layer so that the void is eliminated, thereby forming a void-free barrier layer while a bias voltage is applied; and depositing a dielectric layer over the void-free layer high density plasma chemical vapor deposition.

According to the invention, the void-free barrier layer can be easily fabricated before the dielectric layer is deposited by HDPCVD. The reliability problems of the semiconductor device caused by the void of the barrier layer can be solved.

### BRIEF DESCRIPTION OF THE DRAWINGS

FIGS. 1A to 1C are cross-sections showing the manufacturing steps in the barrier layer/a dielectric layer, in accordance with the prior art.

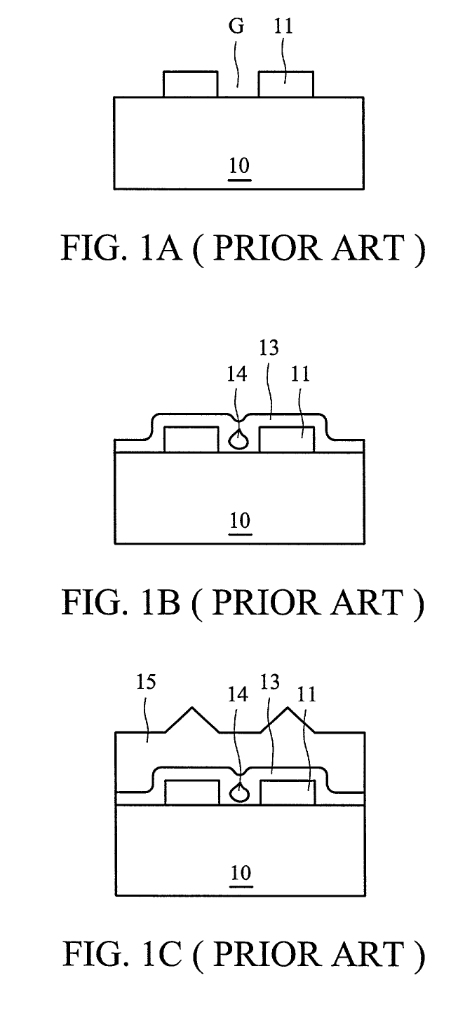

FIGS. 2A to 2D are cross-sections showing the manufacturing steps in the barrier layer/a dielectric layer, in accordance with the present invention.

### DETAILED DESCRIPTION OF THE PREFERRED EMBODIMENTS

The following description will explain the method of manufacturing a void-free barrier layer on a semiconductor substrate according to the preferred embodiment of the invention, which proceeds with reference to the accompanying drawings.

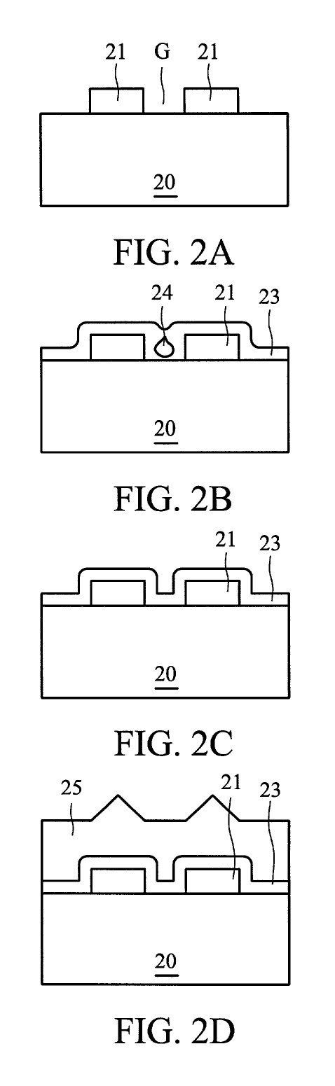

FIG. 2A illustrates a semiconductor substrate 20. Conductive structures 21 such as polysilicon gates are defined on the semiconductor substrate 20. There is a void G between the conductive structures 21.

Next, as shown in FIG. 2B, a barrier layer 23, for example silicon oxide, is deposited by plasma enhanced chemical vapor deposition using Silane (SiH₄) and oxygen (O₂) as reactive gas. A void 24 is generated because of the narrow void G and the insufficient step coverage during deposition.

Referring to FIG. 2C, the semiconductor substrate 20 is placed in a HDPCVD chamber, then argon gas, about 40 to 500 sccm, is introduced into the chamber to produce argon plasma at a power of 1000 to 4000W while a bias voltage is applied by a radio frequency (RF) generator. The barrier layer 23, having a void 24, is sputtered by the argon plasma for 1 to 3 seconds so that the void 24 is eliminated thereby, forming a void-free barrier layer 23′.

Next, as shown in FIG. 2D, a dielectric layer 25, for example undoped silicate glass (USG); phosphosilicate glass (PSG) or borophosphosilicate glass (BPSG), is deposited in the HDPCVD chamber described above using SiH₄ and O₂; SiH₄, O₂ and PH₃ or SiH₄, O₂, PH₃ and boron-containing gas as the reactive gases over the void-free barrier layer 23′. The deposition/sputtering (DIS) ratio for depositing the dielectric layer 24 is between approximately 2.0 to 8.0. Also, the dielectric layer 24 can be inter-layer dielectric (ILD) or pre-metal dielectric (PMD).

The dielectric layer 25 is formed over the void barrier layer 23′ after the void 24 is removed by the argon plasma in the HDPCVD chamber. Furthermore, the dielectric layer 25 is deposited by HDPCVD in the same chamber used to eliminate the void-free barrier.

According to the embodiment of the invention, the void-free barrier layer can be easily fabricated before the dielectric layer is deposited by HDPCVD. The reliability problems of a semiconductor device caused by a void in the barrier layer can be solved.

While the invention has been described with reference to various illustrative embodiments, the description is not intended to be construed in a limiting sense. Various modifications of the illustrative embodiments, as well as other embodiments of the invention, will be apparent to those person skilled in the art upon reference to this description. It is therefore contemplated that the appended claims will cover any such modifications or embodiments as may fall within the scope of the invention defined by the following claims and their equivalents.

What is claimed is:

1. A method of fabricating a void-free barrier layer located on a semiconductor substrate, comprising the steps of:
(a) forming conductive structures on the semiconductor substrate;
(b) depositing a barrier layer over the conductive structures, wherein the barrier layer has a void between the conductive structures;
(c) introducing argon gas into a chamber of high density plasma chemical vapor deposition to sputter the barrier layer so that the void is eliminated.

2. The method of fabricating a void-free barrier layer according to claim 1, further comprising the step of depositing a dielectric layer over the barrier layer by high density plasma chemical vapor deposition.

3. The method of fabricating a void-free barrier layer according to claim 2, wherein the deposition/sputtering (D/S) ratio for depositing the dielectric layer is between approximately 2.0 and 8.0.

4. The method of fabricating a void-free barrier layer according to claim 1, wherein the barrier layer is deposited by plasma enhanced chemical vapor deposition.

5. The method of fabricating a void-free barrier layer according to claim 4, wherein the barrier layer is selected from the group consisting of silicon nitride, silicon oxide, and silicon rich oxide.

6. The method of fabricating a void-free barrier layer according to claim 1, wherein the argon gas is introduced while a bias voltage is applied.

7. The method of fabricating a void-free barrier layer according to claim 1, wherein step (c) the barrier layer is sputtered about 1 to 3 seconds.

8. The method of fabricating a void-free barrier layer according to claim 1, wherein the flow rate of the argon gas is between about 50 to about 400 sccm.

9. The method of fabricating a void-free barrier layer according to claim 1, wherein the conductive structures are gate patterns.

10. A method of fabricating a void-free barrier layer located on a semiconductor substrate, comprising the steps of:
(a) forming gate structures on the semiconductor substrate;
(b) depositing a barrier layer over the gate structures, wherein the barrier layer has a void between the gate structures;
(c) introducing argon gas into a chamber, applying a bias voltage, of high density plasma chemical vapor deposition to sputter the barrier layer so that the void is eliminated thereby forming a void-free barrier layer; and
(d) depositing a dielectric layer over void-free barrier layer by high density plasma chemical vapor deposition in the chamber.

11. The method of fabricating a void-free barrier layer according to claim 10, wherein step (b) the barrier layer is deposited by plasma enhanced chemical vapor deposition.

12. The method of fabricating a void-free barrier layer according to claim 10, wherein the barrier layer is selected from the group consisting of silicon nitride, silicon oxide, and silicon rich oxide.

13. The method of fabricating a void-free barrier layer according to claim 10, wherein the flow rate of the argon gas is between about 50 to about 400 sccm.

14. The method of fabricating a void-free barrier layer according to claim 10, wherein step (c) the barrier layer is sputtered about 1 to 3 seconds.

15. A method of fabricating a void-free barrier layer located on a semiconductor substrate having a barrier layer with a void, comprising the steps of:
placing the semiconductor substrate in a HDPCVD chamber;
introducing an inert gas into the chamber to sputter of the barrier layer so that the void is eliminated, thereby forming a void-free barrier layer while a bias voltage is applied; and
depositing a dielectric layer over the void-free layer high density plasma chemical vapor deposition.

16. The method of fabricating a void-free barrier layer according to claim 15, wherein the inert gas is argon gas.

17. The method of fabricating a void-free barrier layer according to claim 15, wherein the barrier layer is selected from the group consisting of silicon nitride, silicon oxide, and silicon rich oxide.
